(19) United States
(12) Patent Application Publication
(10) Pub. No.: US 2024/0253585 A1
(43) Pub. Date: Aug. 1, 2024

(54) In-Vehicle Control Device and Manufacturing Method

(71) Applicant: HITACHI ASTEMO, LTD., Hitachinaka-shi, Ibaraki (JP)

(72) Inventor: Michihito WATARAI, Hitachinaka (JP)

(21) Appl. No.: 18/559,643

(22) PCT Filed: Feb. 2, 2022
(86) PCT No.: PCT/JP2022/003945

§ 371 Date: Nov. 9, 2023

(30) Foreign Application Priority Data
Jul. 5, 2021 (JP) 2021-111312

(51) Int. Cl. B60R 16/023; H05K 7/20

(52) U.S. Cl. CPC B60R 16/0239; H05K 7/20409

(57) ABSTRACT

In an in-vehicle control device (1) including a base (10), a cover (20) fixed to the base, a circuit board (30) accommodated in the base and the cover, and an electronic component (40) mounted on the circuit board, at least one of the base or the cover is an integrated structure of a plurality of heat dissipation fins (15) and a main body (14), the plurality of heat dissipation fins being made of a portion of one steel plate as a material, and the main body being made of the remaining portion of the steel plate.

### TECHNICAL FIELD

The present invention relates to an in-vehicle control device and a manufacturing method thereof.

### BACKGROUND ART

Various electronic control units (ECUs) such as an ECU that recognizes an external environment from a camera image and an automated driving ECU that determines a travel route from recognized external environment information are mounted on an automobile. In recent years, development of an integrated ECU in which a plurality of ECUs having different functions are integrated has progressed, and improvement of heat dissipation performance has been required more than ever as the amount of generated heat increases. As a heat dissipation structure of an electronic component, a structure in which a heat dissipation fin is erected on a case for storing a circuit board to increase a heat dissipation area is known (PTL 1 or the like).

### CITATION LIST

### Patent Literature

PTL 1: JP 2007-88376 A

### SUMMARY OF INVENTION

### Technical Problem

An in-vehicle control device is required to be lightweight in order not only to improve heat dissipation performance but also to reduce fuel consumption and improve environmental responsiveness. However, a heat dissipation fin of the in-vehicle control device is formed by die-casting, which is a type of metal mold casting method, and the thickness or pitch of the fin is greatly restricted due to the need to press and release a material into and from a mold, and improvement of the heat dissipation performance is not necessarily easy. In addition, it is actually difficult to achieve lightweight due to the nature of the material (for example, AD12) used for die-casting. Also in PTL 1, there is only a description that the heat dissipation fin is made of aluminum, and there is no description of a manufacturing method thereof, but since the thickness of the heat dissipation fin is clearly described as 2 mm, there is no doubt that the heat dissipation fin is die-cast in aluminum.

An object of the present invention is to provide an in-vehicle control device and a manufacturing method thereof capable of achieving both lightweight and heat dissipation performance at a high level.

### Solution to Problem

In order to achieve the above object, according to the present invention, an in-vehicle control device includes: a base; a cover fixed to the base; a circuit board accommodated in the base and the cover; and an electronic component mounted on the circuit board, in which at least one of the base or the cover is an integrated structure of a plurality of heat dissipation fins and a main body, the plurality of heat dissipation fins being made of a portion of one steel plate as a material, and the main body being made of the remaining portion of the steel plate.

### Advantageous Effects of Invention

According to the present invention, it is possible to achieve both lightweight and heat dissipation performance at a high level.

### BRIEF DESCRIPTION OF DRAWINGS

FIG. 1 is a perspective view of an in-vehicle control device according to a first embodiment of the present invention as viewed from a cover side.

FIG. 2 is an exploded view of the in-vehicle control device according to the first embodiment of the present invention.

FIG. 3 is a perspective view of the in-vehicle control device according to the first embodiment of the present invention as viewed from a base side.

FIG. 4 is an enlarged view of a portion IV in FIG. 3.

FIG. 5 is a configuration view of a heat dissipation fin as viewed in a direction of an arrow V in FIG. 4.

FIG. 6 is a view illustrating an attached state of the in-vehicle control device according to the first embodiment of the present invention.

FIG. 7 is a view illustrating an attached state of the in-vehicle control device according to the first embodiment of the present invention as viewed in a direction of an arrow VII in FIG. 6.

FIG. 8 is a perspective view of an in-vehicle control device according to a second embodiment of the present invention as viewed from a base side.

FIG. 9 is a configuration view of a heat dissipation fin provided in a region A of the in-vehicle control device according to the second embodiment of the present invention.

FIG. 10 is a configuration view of a heat dissipation fin provided in a region B of the in-vehicle control device according to the second embodiment of the present invention.

FIG. 11 is a perspective view of an in-vehicle control device according to a third embodiment of the present invention as viewed from a cover side.

FIG. 12 is a perspective view of the in-vehicle control device according to the third embodiment of the present invention as viewed from a base side.

FIG. 13 is a view illustrating an outline of a partial cross section of the in-vehicle control device according to the third embodiment of the present invention.

FIG. 14 is a perspective view of an in-vehicle control device according to a fourth embodiment of the present invention as viewed from a cover side.

FIG. 15 is a perspective view of the in-vehicle control device according to the fourth embodiment of the present invention as viewed from a base side.

FIG. 16 is a view illustrating an outline of a partial cross section of the in-vehicle control device according to the fourth embodiment of the present invention.

FIG. 17 is a view illustrating an outline of a cross section of a general aluminum die-cast fin.

### DESCRIPTION OF EMBODIMENTS

Hereinafter, embodiments of the present invention will be described with reference to the drawings.

### First Embodiment

### In-Vehicle Control Device

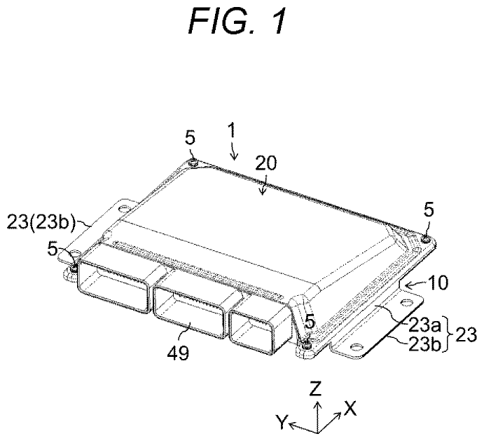

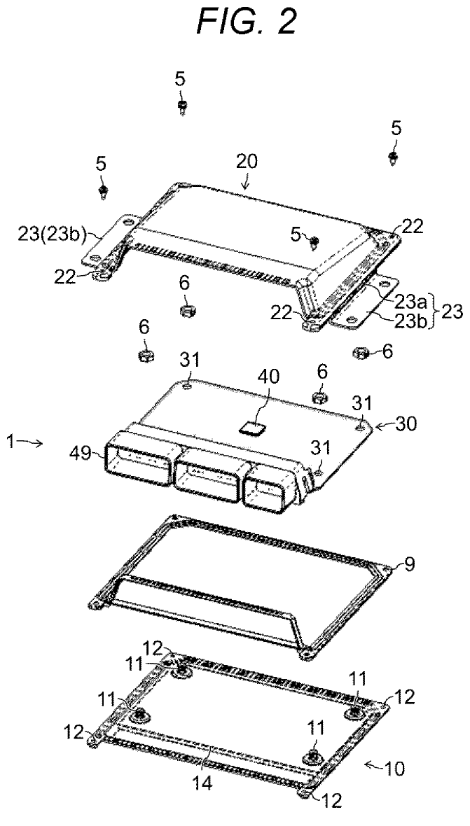

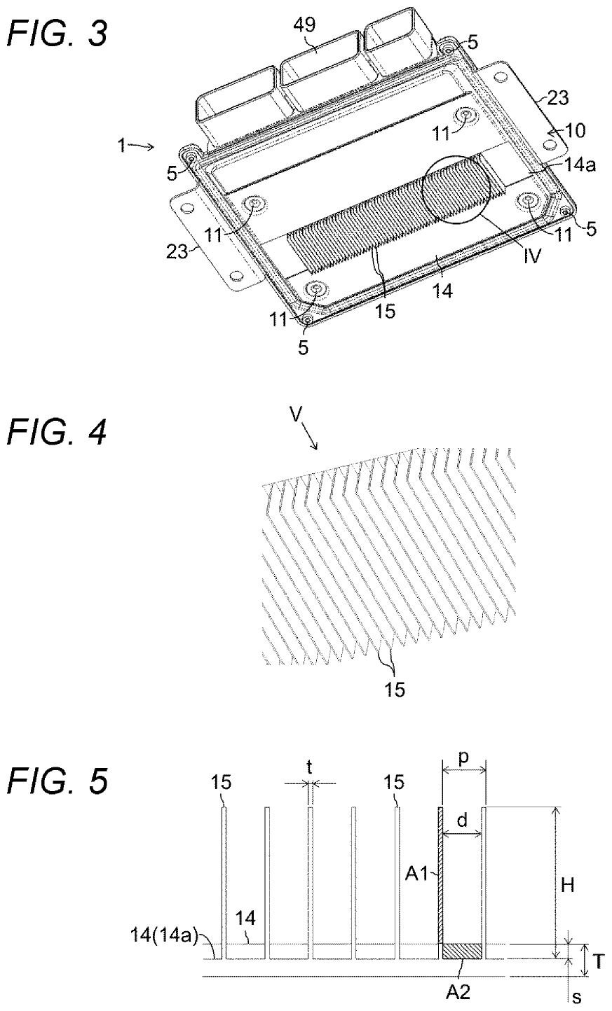

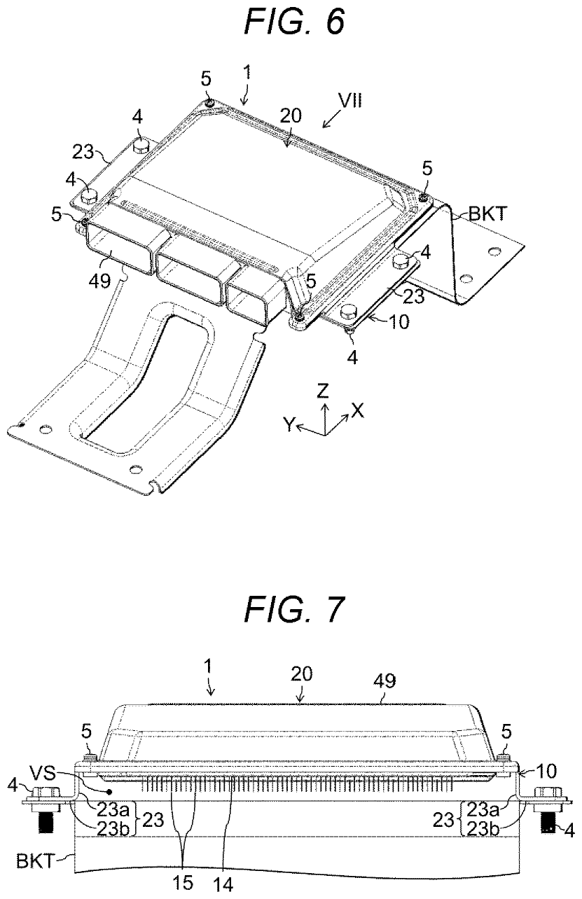

FIG. 1 is a perspective view of an in-vehicle control device according to a first embodiment of the present invention as viewed from a cover side, FIG. 2 is an exploded view, FIG. 3 is a perspective view as viewed from a base side, FIG. 4 is an enlarged view of a portion IV in FIG. 3, and FIG. 5 is a configuration view of a heat dissipation fin as viewed in a direction of an arrow V in FIG. 4. FIG. 6 is a view illustrating an attached state of the in-vehicle control device, and FIG. 7 is a view illustrating an attached state as viewed in a direction of an arrow VII in FIG. 6.

An in-vehicle control device 1 (hereinafter, simply referred to as a control device 1) illustrated in FIGS. 1 to 7 is a type of computer, and is an in-vehicle electronic control unit (ECU) mounted on a structure of an automobile. The control device 1 described in each of the following embodiments is mounted in, for example, an engine room of an automobile, but can also be mounted in a place other than the engine room of the automobile. The control device 1 includes a base 10, a cover 20, a circuit board 30 (FIG. 2), and an electronic component. These constitutional elements will be described below.

### Base

The base 10 is a base structure of the in-vehicle control device 1, and is made of a general-purpose steel plate (hot rolled steel plate or cold rolled steel plate). Specifically, the base 10 is a plate-shaped member having a rectangular shape as a whole, and a plurality of heat dissipation fins 15 (to be described later) are erected by slicing a surface layer of a steel plate and bending and raising (scraping and raising) a root of the sliced portion. Specifically, a steel plate is press-molded to form a basic shape (to be described later) of the base 10, and then a predetermined region of a surface of the pressed steel plate is skived to form the plurality of heat dissipation fins 15. In particular, in the present embodiment, the base 10 is made of an aluminum plate, and is not subjected to coating processing such as plating. As illustrated in FIG. 2, male screw portions 11 protruding upward (toward the cover 20) are provided near four corners of the base 10. In addition, screw holes 12 are provided at four corners of the base 10.

### Cover

The cover 20 is formed in a dome shape protruding in a direction (a Z direction in FIG. 1) opposite to where the base 10 is positioned, forms a housing of the control device 1 together with the base 10, and is fixed to the base 10 with a plurality of screws 5 (four screws in the present embodiment). Each screw 5 is screwed into the screw hole 12 of the base 10 through a through hole 22 (FIG. 2) drilled in each of four corners of the cover 20. By doing so, the cover 20 is fastened to the base 10, and surrounds and protects the circuit board 30 together with the base 10. In the present embodiment, for example, a resin such as polybutylene terephthalate (PBT), polyphenylene sulfide (PPS), or nylon (PA) is adopted as the material of the cover 20, and the weight of the cover 20 is reduced. However, the cover 20 may be made of a metal containing aluminum, iron, or the like as a main component.

In addition, a seal 9 is sandwiched between the base 10 and the cover 20, and waterproofness and airtightness between the base 10 and the cover 20 are enhanced. As the seal 9, for example, an adhesive made of a material such as a silicone-based material, an epoxy-based material, or a urethane-based material, or an O-ring made of a rubber-based material can be used.

In the present embodiment, the control device 1 is attached to a structure of an automobile (for example, an automobile-side bracket BKT illustrated in FIG. 6) by a flange 23. In the present embodiment, the flange 23 is molded integrally with the cover 20, but the flange 23 may be formed on the base 10. In a case where the flange 23 is formed on the base 10, for example, the flange 23 can also be formed when the base 10 is press-molded from the steel plate. The flange 23 is provided at each of opposite ends of the cover 20 in a direction (a Y direction in FIG. 1) orthogonal to a direction (an X direction in FIG. 1) in which the heat dissipation fin 15 to be described later extends along a main body 14 of the base 10. The flange 23 is formed in an L shape including a leg portion 23a extending beyond the base 10 from the cover 20 toward the base 10 (a −Z direction in FIG. 1) and a grounding portion 23b extending outward (±Y direction) from a distal end of the leg portion 23a (FIG. 7). Each grounding portion 23b is fastened to the automobile-side bracket BKT with a plurality of (two in the present embodiment) mounting screws 4, whereby the control device 1 is fixed to the structure of the automobile. In addition, a ventilation space VS (FIG. 7) for allowing air to pass is secured between the structure (automobile-side bracket BKT) of the automobile and the main body 14 of the base 10 by the leg portion 23a. The height (a dimension in the Z direction) of the leg portion 23a is set to be larger than a height H (FIG. 5) of the heat dissipation fin 15 in order to avoid contact between the heat dissipation fin 15 and the structure (automobile-side bracket BKT) of the automobile.

### Circuit Board/Electronic Component

The circuit board 30 is accommodated in the base 10 and the cover 20. The electronic component and a connector 49 are mounted on the circuit board 30. The circuit board 30 has through holes 31 (FIG. 2) at four corners, and is fixed to the base 10 by passing the male screw portions 11 of the base 10 through the through holes 31 and fastening nuts 6 (FIG. 2) to the male screw portions 11.

The connector 49 is made of a resin such as polybutylene terephthalate (PBT), polyamide (PA), or polyphenylene sulfide (PPS). The connector 49 includes a plurality of connector terminals made of a metal containing copper as a main component, and is connected to a connector (not illustrated) at a distal end of a harness extending from a communication partner device on an automobile side. The connector terminal is a terminal for exchanging a voltage and a current with a connection partner, and is connected to a circuit formed on the circuit board 30 by soldering, press fitting, or the like. The connector 49 is exposed from the housing formed by the base 10 and the cover 20, but the seal 9 is also interposed between the connector 49 and the base 10 and the cover 20. As a result, the periphery of the connector 49 is also sealed with the seal 9 to ensure waterproofness.

Although not illustrated, the electronic component may include various electronic components such as a ball grid array (BGA) package and a quad flat no lead package (QFN). FIG. 2 illustrates a BGA package 40.

### Heat Dissipation Fin

As described above, the base 10 is made of a steel plate (an aluminum plate such as JIS A5052 in the present embodiment) which is one general-purpose material. The base 10 is an integrated structure of the plurality of thin plate-shaped heat dissipation fins 15 and the main body 14, the heat dissipation fins 15 being made of a portion of one steel plate as a material, and the main body 14 being made of the remaining portion of the steel plate (that is, a portion other than the heat dissipation fins 15). That is, the main body 14 and the heat dissipation fins 15 are originally the same single steel plate. Each of the heat dissipation fins 15 is a rectangular and smooth thin plate having a uniform shape and size, and the heat dissipation fins 15 are all arranged in parallel at a constant pitch in a region corresponding to a position of a cooling target such as the electronic component mounted on the circuit board 30. In a process of manufacturing the base 10, first, a steel plate is pressed to form a basic shape (a semi-finished product of the base 10) having small irregularities used for alignment of the cover 20 and the seal 9. The heat dissipation fins 15 are obtained by slicing and raising (scraping and raising) a surface layer of a predetermined region of the steel plate by skiving, the steel plate being molded into the basic shape by press working. Unlike cutting and grinding, a scraped-off portion hardly occurs in a steel plate as a material. The surface of the steel plate scraped and raised to form the heat dissipation fins 15 is an outer wall surface (a surface on a side opposite to the circuit board 30) of the control device 1, and, in the present embodiment, is a surface of the control device 1 that faces the structure of the automobile (automobile-side bracket BKT). A base material portion remaining after the scraping and raising are performed to form the heat dissipation fins, that is, a portion of the pressed steel plate excluding the heat dissipation fins 15 is the main body 14 of the base 10.

The plurality of heat dissipation fins 15 are positioned in the ventilation space VS secured between the structure (automobile-side bracket BKT) of the automobile and the main body 14 of the base 10 by the flange 23. The heat dissipation fin 15 is an element exposed on the outer wall surface of an outer frame of the control device 1, and is surrounded and protected by the main body 14 of the base 10, the structure of the automobile, and two flanges 23 as described above. In the present embodiment, each of the heat dissipation fins 15 is formed in parallel to an XZ plane in an XYZ coordinate system illustrated in FIG. 1. Therefore, as described above, the ventilation space VS secured between the flanges 23 arranged on opposite sides of the cover 20 in the Y direction is opened on opposite sides in the X direction, that is, in a direction in which the plurality of heat dissipation fins 15 extend along the surface of the main body 14 of the base 10.

By scraping and raising a partial surface layer of the steel plate as the heat dissipation fins 15, the main body 14 of the base 10 has a thin rectangular parallelepiped recessed portion 14a (FIG. 5) recessed by a predetermined step size s and formed in a surface of the main body 14 (a surface on a side opposite to the circuit board 30). Each of the heat dissipation fins 15 is erected in the recessed portion 14a, and widths (widths in the X direction in this example) of the recessed portion 14a and each of the heat dissipation fins 15 correspond to each other. As illustrated in FIG. 5, each of the plurality of heat dissipation fins 15 has the same thickness at a root portion close to the main body 14 of the base 10 and a distal end portion far from the main body 14.

In the present embodiment, the following relationship is established, in which t represents the thickness of each of heat dissipation fins 15, d represents an inter-surface distance between two adjacent heat dissipation fins 15, H represents the height of each of the heat dissipation fins (a distance from the recessed portion 14a to the distal end of the heat dissipation fin 15), and s represents the step size (the depth of the recessed portion 14a).

t×(H−s)=d×s (Equation 1)

That is, in FIG. 5, a volume of a portion A1 of the heat dissipation fin 15 excluding a portion overlapping the recessed portion 14a corresponds to a volume of an inter-surface portion A2 of two adjacent heat dissipation fins 15 in the recessed portion 14a.

Therefore, by adjusting the thickness t of each of the heat dissipation fins 15, the inter-surface distance d between the two adjacent heat dissipation fins 15, the height H of each of the heat dissipation fins, and the step size s with respect to a thickness T of the steel plate before skiving, a heat dissipation fin of a desired size can be manufactured. In such skiving, thinner heat dissipation fins can be molded at a small pitch as compared with die-cast heat dissipation fins. In the present embodiment, for example, the thickness t of the heat dissipation fin 15 can be set to 0.4 mm or less, which is difficult to achieve for a die-cast heat dissipation fin. In this case, a total surface area of the plurality of heat dissipation fins 15 is eight times or more an area of an installation region (skived region) for the heat dissipation fins 15 in a plan view of the base 10.

### Comparative Example

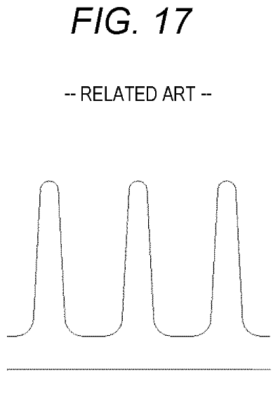

FIG. 17 is a view illustrating an outline of a cross section of a general aluminum die-cast fin. Heat dissipation fins used in a control device (ECU) used in automobiles are generally die cast (for example, die cast in aluminum). Therefore, it is necessary to consider hot water flowability and releasability of a die-cast material to be press-fitted in a mold, and thus the heat dissipation fins are required to have a suitable thickness (for example, about 2 mm) and are required to be arranged at a considerable pitch (for example, about 4 mm). Therefore, the number of heat dissipation fins that can be formed in a region having a certain size is also greatly restricted.

In addition, since a draft angle of the mold is required, the thickness of the die-cast heat dissipation fin increases toward the root as illustrated in FIG. 17. A fillet of the root portion is also necessary, and occurrence of the excessively thick root portion cannot be avoided. In addition, due to the characteristics of a die-cast material (for example, AD12), even an aluminum-based material has a low purity of aluminum, and thus, a specific gravity is larger and salt damage corrosion resistance is lower as compared with a high-purity aluminum plate.

### Effects

(1) In the present embodiment, a general-purpose steel plate is used for the base 10. A die-cast material is not suitable in terms of characteristics for performing scraping and raising to form the heat dissipation fin. By using a general-purpose steel plate, a portion of the surface layer can be thinly sliced and raised as the heat dissipation fin 15. By using the steel plate as the material in this manner, it is possible to provide a large number of heat dissipation fins 15 that are thinner and arranged at a smaller pitch as compared with a case of die-casting, to greatly increase a heat dissipation area as compared with a conventional case, and to greatly improve the heat dissipation performance. In addition, due to material characteristics of a high-purity steel plate, the base 10 is lighter than a conventional configuration using die-casting. Therefore, with the control device 1 of the present embodiment, it is possible to achieve both lightweight and heat dissipation performance at a high level.

(2) Since the heat dissipation fin 15 can be formed by slicing and raising the surface layer of the steel plate, it is not necessary to consider the hot water flowability and releasability in the mold as in the die-casting. There is no need for a fillet at the root of the heat dissipation fin 15 and no need for a draft angle of the mold, and there is no need for an excessive thickness of the root portion.

Therefore, the shape of the heat dissipation fin 15 is not restricted in consideration of the mold, and if a steel plate having a thickness necessary and sufficient for forming the heat dissipation fin 15 is selected, the setting of the height, thickness, pitch, and number of heat dissipation fins 15 can be flexibly changed. The thickness of the steel plate to be used as the material can be easily selected in consideration of the fact that the volumes of the portions A1 and A2 in FIG. 5 correspond to each other as described for the preceding clause (Equation 1). Therefore, the heat dissipation fin 15 can be flexibly designed and manufactured according to the heat dissipation area required according to a heat generation amount of the control device 1, and as in the present embodiment, the total surface area of the heat dissipation fins 15 can be set to eight times or more the area of the installation region for the heat dissipation fins 15 in plan view. Improvement in heat dissipation capability can contribute to improvement in degree of freedom in designing the control device 1 including an electronic component.

In general, the heat dissipation fin may be retrofitted to the housing of the control device by welding, brazing, an adhesive, or the like. On the other hand, since the heat dissipation fin 15 of the present embodiment is an integrated structure made of the same steel plate as the main body of the base 10, unlike a case where the heat dissipation fin is retrofitted, a process such as welding does not occur, and the heat dissipation fin can be manufactured at low cost. The fact that the material is a general-purpose steel plate also contributes to cost reduction. In addition, welding, brazing, and bonding may cause variations in quality, but in the present embodiment, quality stability is also excellent by erecting the heat dissipation fin 15 by machining. Since the base 10 including the heat dissipation fins 15 is integrally formed using the same steel plate, it is advantageous also in terms of strength, and since the entire base 10 is made of the same material having high purity, high thermal conductivity can also be secured.

(3) As described above, the base 10 is manufactured by press-molding a steel plate and then skiving the surface to form the plurality of heat dissipation fins 15. That is, when the control device 1 is assembled, a basic shape having a recessed portion or the like in which the seal 9 and the cover 20 are to be placed is formed by press working, and then the heat dissipation fins 15 are formed by skiving. In addition, it is also possible to skive a predetermined position of the steel plate to form the plurality of heat dissipation fins, and then process the basic shape by press molding. By combining the press working and the skiving in this manner, the degree of freedom of the shape of the base 10 that can be manufactured using a general-purpose steel plate also increases. In addition, by applying the skiving, it is also easy to form the heat dissipation fins 15 by slicing and raising the surface layer of the steel plate.

(4) By using a high-purity aluminum plate as the steel plate, salt damage corrosion resistance is also greatly improved as compared with a die-cast material (for example, AD12) containing many impurities.

(5) Regarding a layout of the heat dissipation fins 15, the ventilation space VS is secured between the structure of the automobile (the automobile-side bracket BKT in the present embodiment) and the main body 14 of the base 10 by the flange 23, and the heat dissipation fins 15 are arranged in the ventilation space VS. As a result, the heat dissipation fins 15 can be surrounded by the structure of the automobile, the main body 14, and the flange 23, and a portion of the main body 14 that is thinned due to the use of the material for the heat dissipation fins 15 can be protected from interference with an obstacle or the like.

(6) In addition, since the ventilation space VS is opened in the direction in which the heat dissipation fin 15 extends along the outer wall surface of the main body 14, the flow of air can be guided to the ventilation space VS along the heat dissipation fin 15. As a result, cooling air can be applied to each of the heat dissipation fins 15, and the heat dissipation capability of the heat dissipation fins 15 can be effectively exhibited.

(7) As described above, since the draft angle of the mold is unnecessary in the present embodiment, the heat dissipation fin 15 can have the same thickness from the root to the distal end. In a case of the die-casting as illustrated in FIG. 17, the root of the heat dissipation fin is thick due to the necessity of the draft angle of the mold, and a heat capacity is large. On the other hand, in the present embodiment, since the root portion of the heat dissipation fin 15 can also be thinned similarly to the distal end portion, heat generated by the electronic component and transmitted through the main body 14 can be efficiently dissipated also at the root portion of the heat dissipation fin 15.

(8) Since the main body 14 in the installation region for the heat dissipation fins 15 is thinner than that in a non-installation region for the heat dissipation fins 15, for example, in a case where an air flows between the heat dissipation fins 15, a thinned portion of the main body 14 can contribute to improvement of the heat dissipation performance.

(9) in the present embodiment, the heat dissipation fin 15 is erected in the recessed portion 14a that is a thin portion of the main body 14. Therefore, in addition to the effect (8) of the thinning of the main body 14, unlike a case where the heat dissipation fins 15 are erected at other portions of the main body 14, the heat dissipation fins 15 can be shifted toward the circuit board 30 by the depth of the recessed portion 14a even in a case of the heat dissipation fins of the same size. As a result, a volume actually occupied by the control device 1 and an installation space of the control device 1 are smaller as compared with other control devices having an equivalent heat dissipation area, and the degree of freedom of the layout of the control device 1 is increased.

### Second Embodiment

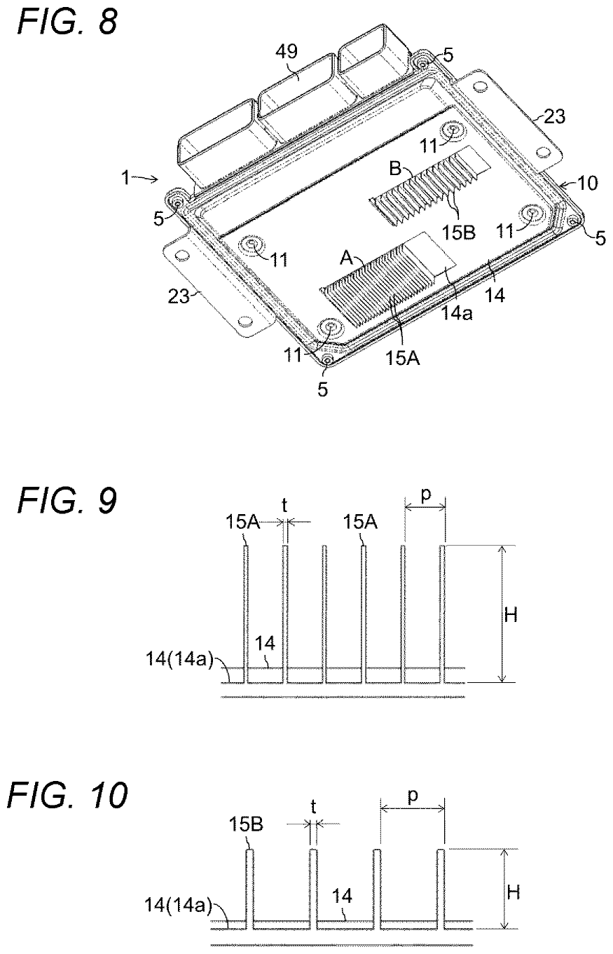

FIG. 8 is a perspective view of an in-vehicle control device according to a second embodiment of the present invention as viewed from a base side, and corresponds to FIG. 3 of the first embodiment. FIG. 9 is a configuration view of a heat dissipation fin provided in a region A illustrated in FIG. 8, and FIG. 10 is a configuration view of a heat dissipation fin provided in a region B illustrated in FIG. 8, and both correspond to FIG. 5 of the first embodiment. In FIGS. 8 to 10, the same or corresponding parts as those in the first embodiment are denoted by the same reference signs as those in the previously described drawings, and a description thereof is omitted.

The present embodiment is different from the first embodiment in that a plurality of heat dissipation fins are provided in a plurality of separated regions (two regions A and B in this example) of the base 10, and a thickness t, a height H, and a pitch p of the heat dissipation fins are different for each region.

In the present embodiment, the thickness t, the height H, the pitch p, and the number of heat dissipation fins 15A in the region A are all different from those of heat dissipation fins 15B in the region B. Each of the heat dissipation fins 15A and 15B is an element corresponding to the heat dissipation fin 15 of the first embodiment, and is formed in the same manner as the heat dissipation fin 15. For example, the heat dissipation fin 15B in the region B is set to be larger in thickness t and pitch p, and the heat dissipation fin 15A in the region A is set to be larger in height H and number. However, the values of the thickness t, the height H, the pitch p, and the number are appropriately set according to heat dissipation areas necessary for the regions A and B, and it is sufficient to change any one of them according to the necessary heat dissipation area.

Other points of the present embodiment are similar to the first embodiment.

As in the first embodiment, since the degree of freedom in designing the heat dissipation fins is high, a plurality of installation regions for the heat dissipation fins can be provided according to the positions of the electronic components mounted on the circuit board 30 inside the control device 1, and the dimensions and the number of the heat dissipation fins can be flexibly set according to the amount of heat generated by the electronic components to be cooled. As a result, the heat dissipation amount can be controlled for each portion according to the amount of generated heat and the layout of various electronic components, and temperature distribution can be equalized while avoiding heat concentration of the housing of the control device 1.

The configuration of the present embodiment is also applicable to a third embodiment and a fourth embodiment to be described below.

### Third Embodiment

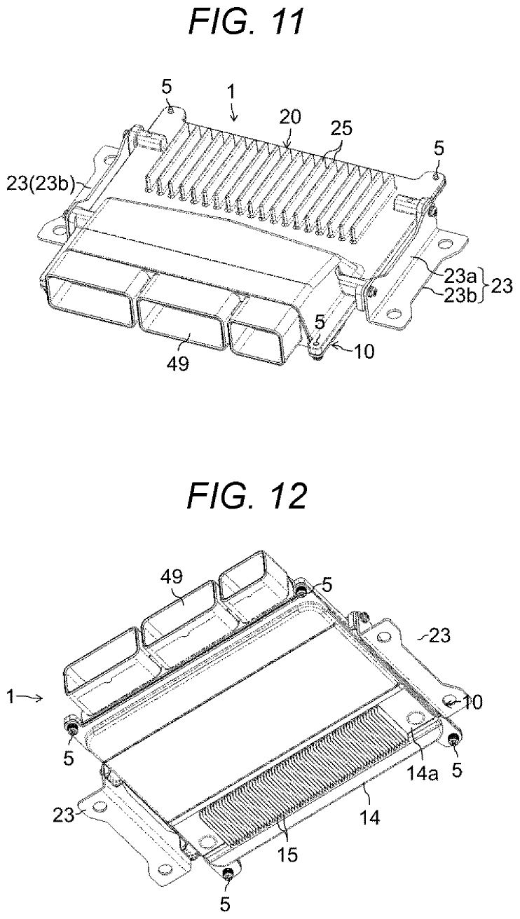

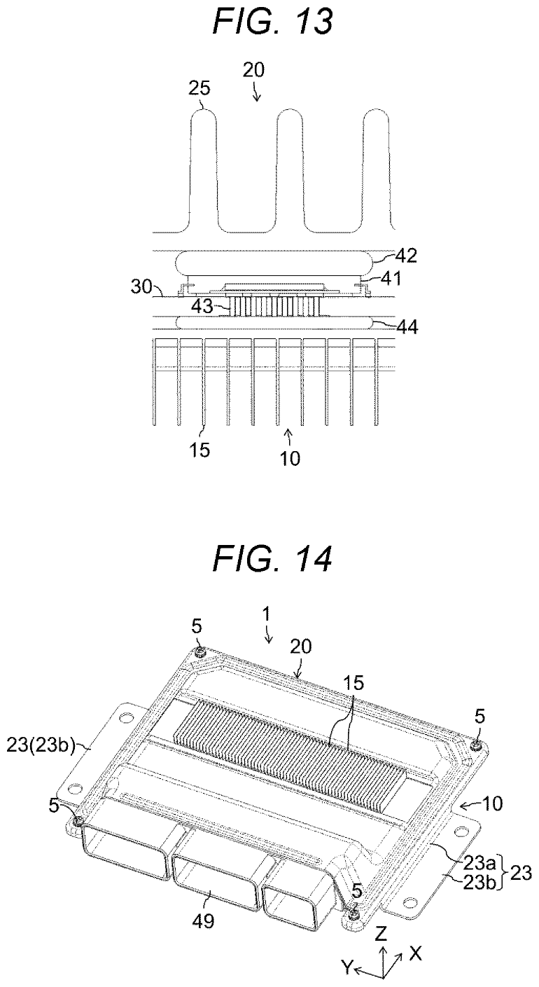

FIG. 11 is a perspective view of an in-vehicle control device according to a third embodiment of the present invention as viewed from a cover side, FIG. 12 is a perspective view of the in-vehicle control device as viewed from a base side, and FIG. 13 is a view illustrating an outline of a partial cross section. FIGS. 11 and 12 correspond to FIGS. 1 and 3 of the first embodiment. In FIGS. 11 to 13, the same or corresponding parts as those in the described embodiments are denoted by the same reference signs as those in the previously described drawings, and a description thereof is omitted.

In the present embodiment, one of a base 10 and a cover 20 (the base 10 in this example) is an integrated structure of a plurality of heat dissipation fins 15 made of a steel plate and a main body 14 as in the first embodiment. A difference from the first embodiment is that the other of the base 10 and the cover 20 (the cover 20 in this example) is die-cast and includes die-cast fins 25.

In the present embodiment, the cover 20 of the control device 1 is made of die-cast aluminum unlike the first embodiment, and the fins 25 made of die-cast aluminum are provided on an outer wall surface (a surface on an opposite side to a circuit board 30 and the base 10) of the cover 20. As the base 10, a base obtained by press-molding a steel plate and performing skiving to form the heat dissipation fin 15 is adopted as in the first embodiment. The heat dissipation fins 15 of the base 10 extend toward a structure of an automobile (for example, an automobile-side bracket BKT) (downward in FIG. 13), whereas the fins 25 of the cover 20 extend toward a side opposite to the structure of the automobile (upward in FIG. 13). As illustrated in FIG. 13, the die-cast fin is thicker than the heat dissipation fin 15 of the base 10 for the convenience of manufacturing the die-cast fin 25 using a mold, and the number of die-cast fins 25 is smaller due to a large pitch.

In FIG. 13, a surface of an electronic component 41 to be cooled mounted on the circuit board 30 is in contact with an inner wall surface of an installation region for the fins 25 of the cover 20 via an upper surface thermal conductive grease 42. As a result, heat is transferred from the electronic component 41 to the cover 20 via the upper surface thermal conductive grease 42, and is dissipated from the fins 25. On the other hand, the electronic component 41 is in contact with an inner wall surface of an installation region for the heat dissipation fins 15 of the base 10 via thermal vias 43 and a lower surface thermal conductive grease 44. Therefore, heat is transferred from the electronic component 41 to the base 10 via the thermal vias 43 and the lower surface thermal conductive grease 44, and is dissipated from the heat dissipation fins 15. Although not illustrated in detail in the first embodiment and the second embodiment, a structure of heat transfer from the electronic component to the heat dissipation fin 15 is the same as the structure illustrated in FIG. 13 in the first and second embodiments.

As in the present embodiment, the heat dissipation fin 15 cut from the steel plate can be combined with a component adopting a conventional die-cast fin structure. Since the cover 20 side does not face the structure of the automobile, the thick die-cast fins 25 can be applied to this portion although the fins 25 are exposed. By adopting the configuration as in the present embodiment, heat can be dissipated from the base 10 side by the heat dissipation fins 15 and from the cover 20 side by the die-cast fins 25, and further improvement in cooling efficiency can be expected by dissipating heat from upper and lower surfaces of the control device 1.

### Fourth Embodiment

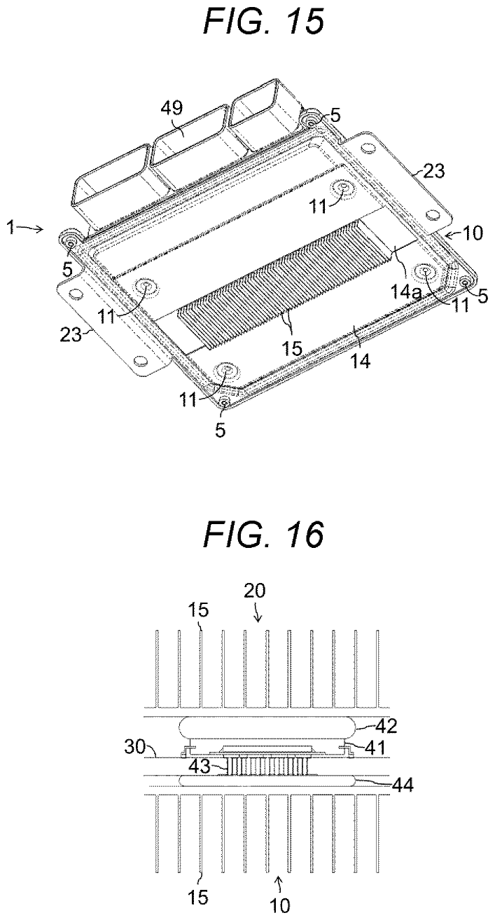

FIG. 14 is a perspective view of an in-vehicle control device according to a fourth embodiment of the present invention as viewed from a cover side, FIG. 15 is a perspective view of the in-vehicle control device as viewed from a base side, and FIG. 16 is a view illustrating an outline of a partial cross section. FIGS. 14 and 15 correspond to FIGS. 1 and 3 of the first embodiment. FIG. 16 corresponds to FIG. 13 of the third embodiment. In FIGS. 14 to 16, the same or corresponding parts as those in the described embodiments are denoted by the same reference signs as those in the previously described drawings, and a description thereof is omitted.

The present embodiment is different from the first embodiment in that both a base 10 and a cover 20 are an integrated structure of a plurality of heat dissipation fins made of a steel plate and a main body as a remaining portion, similarly to the base 10 of the first embodiment.

In the present embodiment, the cover 20 of the control device 1 is made of a steel plate similarly to the base 10, and is molded into a basic shape by press working, and then, for example, a surface layer of an outer wall surface is sliced and raised by skiving to form a plurality of heat dissipation fins 15. The outer wall surface to be skived is a surface of the cover 20 on an opposite side to a circuit board 30 and the base 10. The heat dissipation fins 15 of the base 10 extend toward a structure of an automobile (for example, an automobile-side bracket BKT) (downward in FIG. 16), whereas the heat dissipation fins 15 of the cover 20 toward a side opposite to the structure of the automobile (upward in FIG. 16). Since the heat dissipation fins 15 of the cover 20 are exposed without facing the structure of the automobile, a height H of the heat dissipation fin 15 is suppressed in such a way that the heat dissipation fin 15 does not protrude from an upper end surface of a connector 49 in a Z direction. Configurations and forming methods of the heat dissipation fins 15 of the cover 20 and the base 10 are similar to each other.

In the example of FIG. 16, heat is transferred from an electronic component 41 to the base 10 via thermal vias 43 and a lower surface thermal conductive grease 44, and is dissipated from the heat dissipation fins 15 of the base 10. In addition, heat generated by the electronic component 41 is also transferred to the cover 20 via an upper surface thermal conductive grease 42, and is also dissipated from the heat dissipation fins 15 of the cover 20.

According to the present embodiment, the heat dissipation fins 15 are applied to upper and lower surfaces of the control device 1, and a heat dissipation area can be doubled as compared with the first embodiment, and the cooling efficiency can be expected to be improved accordingly.

### Modified Example

In the embodiment in which the heat dissipation fin 15 cut from the steel plate is provided only on one of the base 10 and the cover 20, a configuration in which the heat dissipation fin 15 is provided on the base 10 has been described as an example, but the heat dissipation fin 15 may be provided on the cover 20 instead of the base 10. Although a general-purpose aluminum plate is exemplified as the steel plate from which the heat dissipation fin 15 is cut, for example, a steel plate of another material such as an iron plate or a copper plate suitable for skiving may be adopted. However, in a case where salt damage corrosion resistance is required, the iron plate or the copper plate is desirably subjected to coating processing such as plating after the heat dissipation fins 15 are formed to enhance the salt damage corrosion resistance. In other words, it is a great advantage to selecting an aluminum plate that high salt damage corrosion resistance can be obtained without performing such coding processing.

### REFERENCE SIGNS LIST

1 in-vehicle control device
10 base
14 main body
14a recessed portion
15, 15A, 15B heat dissipation fin
20 cover
23 flange
25 die-cast fin
30 circuit board
40 BGA package (electronic component)
41 electronic component
d inter-surface distance
H height
p pitch
s step size
t thickness
VS ventilation space (space)

1. An in-vehicle control device comprising:
a base;
a cover fixed to the base;
a circuit board accommodated in the base and the cover; and
an electronic component mounted on the circuit board,
wherein at least one of the base or the cover is an integrated structure of a plurality of heat dissipation fins and a main body, the plurality of heat dissipation fins being made of a portion of one steel plate as a material, and the main body being made of a remaining portion of the steel plate.

2. The in-vehicle control device according to claim 1, wherein each of the plurality of heat dissipation fins has the same thickness at a root portion close to the main body and at a distal end portion far from the main body.

3. The in-vehicle control device according to claim 1, wherein in the main body, an installation region for the plurality of heat dissipation fins is thinner than a non-installation region for the plurality of heat dissipation fins.

4. The in-vehicle control device according to claim 1, wherein
the main body has a recessed portion recessed by a predetermined step size and formed in a surface of the main body, and
the plurality of heat dissipation fins are erected in the recessed portion.

5. The in-vehicle control device according to claim 4, wherein a relationship indicated by t×(H−s)=d×s is established, in which t represents a thickness of the heat dissipation fin, d represents an inter-surface distance between two adjacent heat dissipation fins, H represents a height of the heat dissipation fin, and s represents the step size.

6. The in-vehicle control device according to claim 1, wherein the steel plate is an aluminum plate.

7. The in-vehicle control device according to claim 1, wherein a total surface area of the plurality of heat dissipation fins is eight times or more an area of an installation region for the plurality of heat dissipation fins in plan view of the main body.

8. The in-vehicle control device according to claim 1, wherein the plurality of heat dissipation fins are portions formed by slicing and raising a surface layer of the steel plate.

9. The in-vehicle control device according to claim 1, wherein at least one of the base or the cover on which the plurality of heat dissipation fins are provided is formed by skiving a surface of the steel plate, or press-molding the steel plate and then skiving the surface of the steel plate to form the plurality of heat dissipation fins.

10. The in-vehicle control device according to claim 1, further comprising a flange for attachment to a structure of an automobile,
wherein the plurality of heat dissipation fins are provided on the base, and
the plurality of heat dissipation fins are arranged in a space secured between the structure and the main body of the base by the flange.

11. The in-vehicle control device according to claim 10, wherein the space is opened in a direction in which the plurality of heat dissipation fins extend along a surface of the main body.

12. The in-vehicle control device according to claim 1, wherein a plurality of the heat dissipation fins are provided in each of a plurality of regions of at least one of the base or the cover, and at least one of a thickness, a height, a pitch, or the number of the plurality of heat dissipation fins is different for each region.

13. The in-vehicle control device according to claim 1, wherein
one of the base and the cover is an integrated structure of the plurality of heat dissipation fins and the main body made of the steel plate, and
the other of the base and the cover includes die-cast fins.

14. The in-vehicle control device according to claim 1, wherein both the base and the cover are an integrated structure of the plurality of heat dissipation fins and the main body made of the steel plate.

15. A manufacturing method of an in-vehicle control device including a base, a cover fixed to the base, a circuit board accommodated in the base and the cover, and an electronic component mounted on the circuit board, the manufacturing method comprising:
slicing and raising a surface layer of a steel plate or a surface layer of a press-molded steel plate of at least one of the base or the cover to form a plurality of heat dissipation fins.
